(19) United States
(12) Patent Application Publication
(10) Pub. No.: US 2010/0124138 A1
(43) Pub. Date: May 20, 2010

(54) Semiconductor memory device having variable-mode refresh operation

(76) Inventors: Dong-Hyuk Lee, Seoul (KR); Jung-Bae Lee, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/585,317

(22) Filed: Sep. 11, 2009

(30) Foreign Application Priority Data
Nov. 17, 2008 (KR) 10-2008-0113856

(51) Int. Cl. G11C 7/00; G11C 8/00

(52) U.S. Cl. 365/222; 365/230.03

(57) ABSTRACT

A semiconductor memory device includes a bit line sense amplifier, a bit line pair that includes a bit line and a complementary bit line, the bit line and the complementary bit line of the bit line pair each being coupled to the bit line sense amplifier, a memory cell array having a plurality of memory banks, the memory banks including word lines and a plurality of memory cells, and a word line activation control unit that performs a control to access data corresponding to an externally same address in at least two memory cells by simultaneously activating a predetermined number of word lines from among the word lines sharing the bit line sense amplifier, and the word line activation control unit operates in response to a determination mode allowing signal that is set in accordance with a used memory density.

### BACKGROUND

1. Field

Embodiments relate to a semiconductor memory device having a variable-mode refresh operation.

2. Description of the Related Art

Semiconductor memory devices, e.g., dynamic random access memory (hereafter, referred to as ‘DRAM’), are increasingly becoming high speed and highly integrated. Increases in speed and device density, however, may result in increased power consumption.

A DRAM having one access transistor and one storage capacitor as a unit memory cell is often employed as a main memory of an electronic system. In the DRAM, data stored as a charge in a memory cell disappears over time due to leakage current. It is therefore required to cyclically read out data stored in a memory cell and then again store the data, this cycle being called a refresh operation. When a cycle of refresh is extended, i.e., the frequency of the refresh is reduced, power consumption is reduced correspondingly. The refresh operation of the DRAM may be, e.g., an auto-refresh, a self-refresh, etc. Even if an external data access is not performed, a self-refresh may be performed internally in the memory device.

A memory chip generally includes a plurality of memory banks. Respective memory banks may store a predetermined quantity of data. In a general DRAM, the refresh operation must be performed for all memory banks, regardless of whether data is stored in the memory cells of the memory banks. This brings about a drop of efficiency. Further, a memory unit (to remember as to whether which cell arrays store data) may be additionally required within the memory to detect whether data is stored in respective cells of the memory bank.

One possibility for improving the efficiency of maintaining data is a partial array self-refresh (PASR), which may be performed only for memory bank or banks having data stored therein. This may reduce the consumption of power in the refresh operation.

For example, in four memory banks, a refresh may be performed for all the four memory banks in a full array mode, or a refresh operation may be performed for two memory banks in a ½ (half) array mode, or a refresh operation may be performed for one memory bank in a ¼ array mode. However, advances are needed to further reduce power consumption and improve efficiency.

### SUMMARY

Embodiments are therefore directed to a semiconductor memory device having a variable-mode refresh operation, which substantially overcomes one or more of the problems due to the limitations and disadvantages of the related art.

It is therefore a feature of an embodiment to provide a semiconductor memory device having a memory density that is selectable per memory channel.

It is therefore another feature of an embodiment to provide a memory device having a memory density that is selectable during operation.

At least one of the above and other features and advantages may be realized by providing a semiconductor memory device, including a bit line sense amplifier, a bit line pair that includes a bit line and a complementary bit line, the bit line and the complementary bit line of the bit line pair each being coupled to the bit line sense amplifier, a memory cell array having a plurality of memory banks, the memory banks including word lines, and a plurality of memory cells coupled to each word line and coupled to at least one line of the bit line pair, and a word line activation control unit. The word line activation unit may perform a control to access data corresponding to an externally same address in at least two memory cells by simultaneously activating a predetermined number of word lines from among the word lines sharing the bit line sense amplifier, and the word line activation control unit may operate in response to a determination mode allowing signal that is set in accordance with a used memory density.

The determination mode-allowing signal may be varied by a mode register set signal.

The predetermined number of word lines activated simultaneously may be changed by a change of the mode register set signal, and then, when a self-refresh starts, a self-refresh cycle may be changed depending on the mode register set signal.

The word line activation control unit may include a mode register set unit receiving the mode register set signal and generating the determination mode-allowing signal, an address and refresh control unit generating an address for an access of data and performing a refresh operation for data preservation in response to the determination mode allowing signal, and a row decoder coupled to the address and refresh control unit, the row decoder simultaneously activating the predetermined number of word lines among the word lines sharing the bit line sense amplifier by performing a row address decoding operation in response to the determination mode allowing signal.

The memory device may include at least two ports, the used memory density being selected per-port.

The used memory density may be changeable during operation of the device.

The data in the at least two memory cells corresponding to the externally same address data may be accessed using a same bit line sense amplifier.

The plurality of word lines may all be disposed collectively on one line of the bit line pair.

The plurality of word lines may be divided into respective groups on the bit line and the complementary bit line of the bit line pair.

Data of opposite logic may be respectively written to a first memory cell coupled to the bit line and a word line in a first group and to a second memory cell coupled to the complementary bit line and a word line in a second group.

At least one of the above and other features and advantages may also be realized by providing a semiconductor memory device, including a bit line sense amplifier, a bit line pair that includes a bit line and a complementary bit line, the bit line and the complementary bit line of the bit line pair each being coupled to the bit line sense amplifier, a memory cell array having a plurality of memory banks, the memory banks including word lines, and a plurality of memory cells coupled to each word line and coupled to at least one line of the bit line pair, and a word line activation control unit. The word line activation unit may perform a control to access data corresponding to an externally same address in memory cells adapted in numbers of 2n, n being a natural number, by simultaneously activating a predetermined number of word lines from among the word lines sharing the bit line sense amplifier in response to a mode register set signal.

When the number of activated memory cells is increased, a self-refresh cycle may increase.

The plurality of word lines may all be disposed collectively on one line of the bit line pair.

The plurality of word lines may be divided into respective groups on the bit line and the complementary bit line of the bit line pair.

Data of opposite logic may be respectively written to a first memory cell coupled to the bit line and first word line in a first group and to a second memory cell coupled to the complementary bit line and a second word line in a second group.

### BRIEF DESCRIPTION OF THE DRAWINGS

The above and other features and advantages will become more apparent to those of ordinary skill in the art by describing in detail example embodiments with reference to the attached drawings, in which:

FIG. 1 illustrates a block diagram of semiconductor memory device according to a first embodiment;

FIG. 2 illustrates an example of a word line activation control according to a second embodiment;

FIG. 3 illustrates an example of a word line activation control according to a third embodiment;

FIG. 4 illustrates an embodiment of row decoder shown in FIG. 1; and

FIG. 5 illustrates an operation per bank in memories of mobile devices according to a fourth embodiment; and

FIG. 6 illustrates an operation per bank in memories of mobile devices according to a fifth embodiment; and

FIGS. 7 and 8 illustrate circuit diagrams of comparative memory cell arrays.

### DETAILED DESCRIPTION

Korean Patent Application No. 10-2008-0113856, filed on Nov. 17, 2008, in the Korean Intellectual Property Office, and entitled: “Semiconductor Memory Device Having Variable-Mode Refresh Operation,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. In the drawing figures, the dimensions of layers and regions may be exaggerated for clarity of illustration. Like reference numerals refer to like elements throughout.

A semiconductor memory device according to embodiments, wherein a variable-mode refresh may be selected according to a used memory channel, is described below. A detailed description for a basic data access operation and its related general internal circuits in known-semiconductor manufacturing process and DRAM is omitted for clarity, such information being known to those of skill in the art and set forth in, e.g., U.S. Patent Application Publication No. 2007/0171753 A1, which is hereby incorporated by reference in its entirety and for all purposes.

Unlike the partial array self refresh (PASR) operation, it may be useful to provide a user-selectable refresh requirement amount and memory array density according to a used memory channel (aka memory port). In particular, a refresh cycle of a memory cell array may be prolonged (i.e., the frequency at which memory cells in the array are refreshed may be decreased) by selecting the memory array density, e.g., by providing a signal, setting a flag or a bit, etc., during operation of the memory device. In a memory of a mobile device, which may need to provide low power consumption, the power consumption may be reduced by prolonging the refresh period (i.e., by reducing the refresh frequency) according to the density selected during operation.

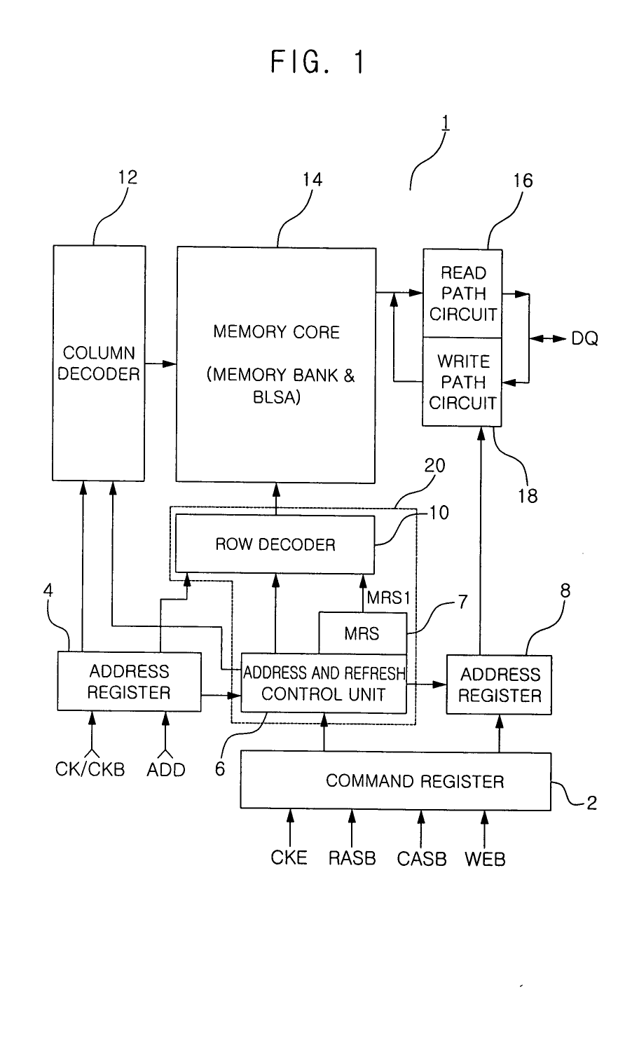

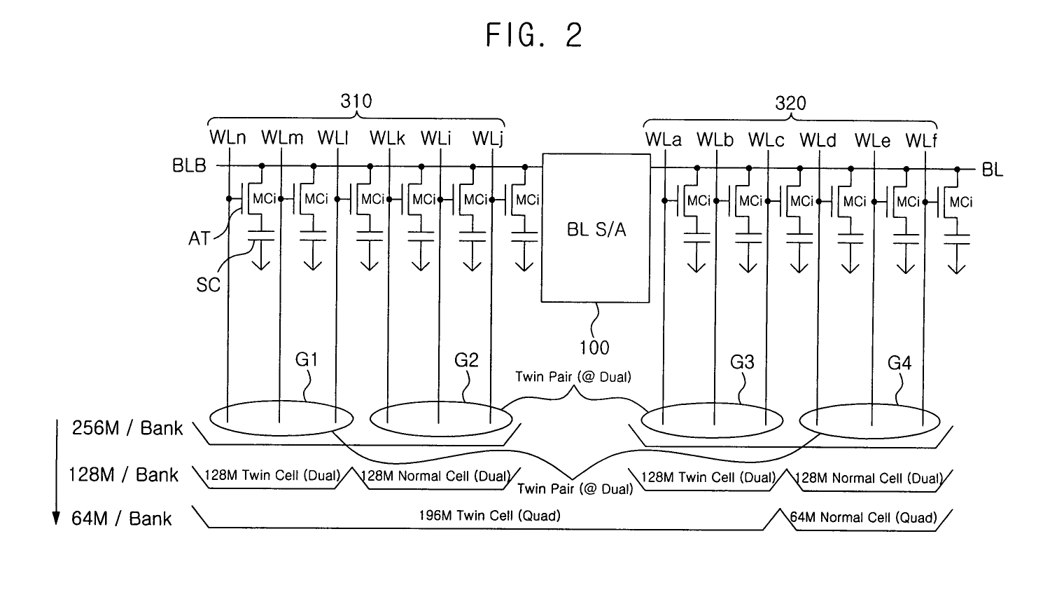

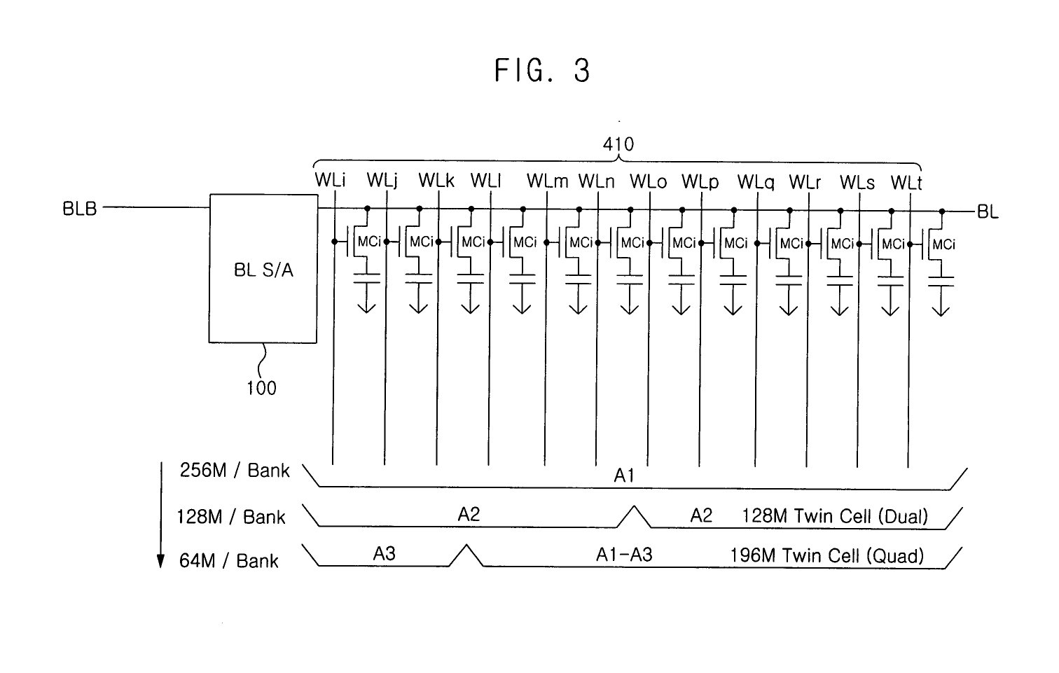

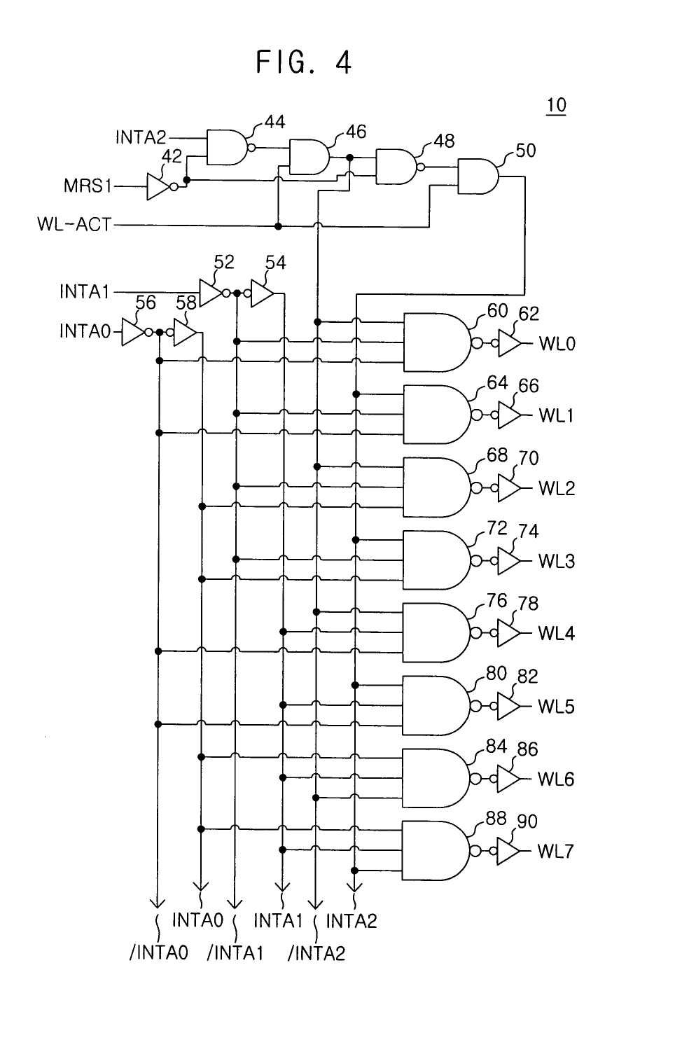

FIG. 1 illustrates a semiconductor memory device 1 according to a first embodiment. Memory banks of the semiconductor memory device 1 of FIG. 1 may be configured as described below in connection with FIGS. 2 and 3. Further, the semiconductor memory device 1 may include a row decoder 10 as described below in connection with FIG. 4. The semiconductor memory device 1 may change a refresh operation cycle depending on a density decision mode, which may be set by the user.

Referring to FIG. 1, the semiconductor memory device 1 may include a command register 2 receiving signals CKE, RASB, CASB and WEB, an address register 4 receiving clock and inverted clock signals CK and CKB (CK bar) and address signal ADD, an address and refresh control unit 6, a mode register set unit (MRS) 7 providing a signal MRS1, an address register 8, the row decoder 10, a column decoder 12, a memory core 14, a read path circuit 16, and a write path circuit 18. The read path circuit 16 may transmit data to I/O terminals DQ and the write path circuit 18 may receive data from the I/O terminals DQ.

The memory core 14 may include a bit line sense amplifier (BLSA) 100 (described in detail below) coupled to a bit line pair (BL-BLB). The memory core 14 may also include a memory cell array (described below in connection with FIGS. 2 and 3). The memory cell array may include a plurality of memory banks. Each memory bank may include a plurality of memory cells (each having an access transistor and a storage capacitor) coupled to each word line and coupled to at least one bit line of the bit line pair BL-BLB.

Referring to FIG. 1, a word line activation control unit 20 may include the mode register set unit 7, which receives an applied “mode register set signal” MRSS and generates the signal MRS1, a “determination mode allowing signal.” The word line activation control unit 20 may also include the address and refresh control unit 6, which generates an address for an access of data and performs a refresh operation for a preservation of data in correspondence with the determination mode applying signal MSR1. The word line activation control unit 20 may also include the row decoder 10, which is coupled to the address and refresh control unit 6, and which performs row address decoding in response to the determination mode applying signal MRS1 such that a determined number of word lines among the word lines sharing the bit line sense amplifier 100 are simultaneously activated.

The word line activation control unit 20 may perform a control operation of simultaneously activating a determined number of word lines among the word lines sharing the bit line sense amplifier 100 in response to the determination mode applying signal MRS1 (MSR1 being decided by a user density selection). The word line activation control unit 20 may access (write and/or read) data corresponding to an externally equal address to at least two memory cells.

The read path circuit 16 may include a local input/output line precharging and equalizing unit, a local input/output line sense amplifier, a global input/output line sense amplifier, and an output buffer. The write path circuit 18 may include an input buffer, a global input/output line driver, and a local input/output line driver.

In an operation to read data, data stored in a memory cell is sensed and amplified by the bit line sense amplifier 100 on a bit line pair BL-BLB, and may then be transferred to a local input/output line pair when a column selection line (CSL) signal is activated. To transfer bit line data to a local input/output line, a precharge operation for the local input/output line may be performed and a potential (i.e., voltage) difference developing operation may be performed.

Before the CSL is activated, the local input/output line pair may be precharged to a given voltage level. When the CSL is activated, the precharged-charge escapes from one line of the local input/output line pair to one bit line of the bit line pair BL-BLB. Accordingly, a potential difference between a complementary local input/output line and a local input/output line (constituting the local input/output line pair) is developed, and an amplitude of the potential difference becomes larger with increasing time. The local input/output line sense amplifier senses and amplifies data on the local input/output line pair, and then applies the data to the global input/output line sense amplifier through a global input/output line pair. The global input/output line sense amplifier finally senses and amplifies the data and applies it to the output buffer, thereby performing the data read operation through the read path circuit.

FIG. 2 illustrates an example of the word line activation control according to a second embodiment. FIG. 3 illustrates an example of the word line activation control according to a third embodiment. As described above, the word line activation control unit 20 may include the row decoder 10, the mode register set unit (MRS) 7, and the address and refresh control unit 6. The structure of the bit line sense amplifier 100 and a memory bank in the memory core 14 may be as illustrated in FIG. 2 or 3.

Referring to FIGS. 2 and 3, a unit memory cell MC1 (where ‘i’ is a natural number), multiples of which are combined to form a memory bank in the memory core 14, may include one access transistor AT and one storage capacitor SC. Word lines may be coupled to respective gates of the access transistors AT of the memory cells MC1.

Referring to the second embodiment illustrated in FIG. 2, a twin cell pair may be provided by coupling memory cells with respective ones of a bit line BL and a complementary bit line BLB (bit line bar), which together constitute a bit line pair BL-BLB. Drains/sources of the access transistors AT may be individually coupled to the lines of the bit line pair BL-BLB. The bit line sense amplifier 100 may be coupled to the bit line BL and the complementary bit line BLB of the bit line pair BL-BLB. The bit line sense amplifier 100 may sense and amplify data stored in a memory cell within the memory core 14, which appears as a potential difference on the bit line pair BL-BLB in a read operation.

In a data access operation, e.g., a read operation (or a write operation) of a semiconductor memory device having 256 Mbit (megabit) per bank, a density, e.g., 128 Mbit or 64 Mbit, may be selected by the mode register set signal MRSS.

In FIG. 2, a memory bank G2 and a memory bank G3 may form a twin pair in dual-configuration structure. In detail, the memory bank G2 of a memory block 310 (shown to the left of the bit line sense amplifier 100) coupled to the complementary bit line BLB, and the memory bank G3 of a memory block 320 (shown to the right of the bit line sense amplifier 100) coupled to the bit line BL, constitute a “twin” (or “twinned”) pair in the dual structure with a density of 256 Mbit. Similarly, a memory bank G1 and a memory bank G4 also constitute a twin pair in the dual structure, and have a density of 256 Mbit.

When the density selected by the mode register set signal MRSS is 128 Mbit per bank, the memory bank G1 provides twin cells TC of 128 Mbit in the dual structure, and the memory bank G2 provides normal cells NC of 128 Mbit in the dual structure. That is, the normal cell NC is the “real” cell, and the twin cell (or “twinned cell”) is an opposite-logic copy, i.e., twin.

The memory bank G3 and the memory bank G4 are a 128 Mbit twin cell TC in the dual structure and a 128 Mbit normal cell NC in the dual structure, respectively.

When the density of 64 Mbit is selected, four word lines among the word lines sharing the bit line sense amplifier 100 are simultaneously activated, and data corresponding to an externally equal address may be written to (or read from) four memory cells in a quad-configured structure. In selecting a density of 64 Mbit per bank, the memory banks G1, G2, and G3 have twin cells TC of a total of 196 Mbit in the quad structure, and the memory bank G4 has normal cells NC of 64 Mbit in the quad structure. That is, there are three twinned cells in for each normal cell NC in the quad structure.

When the density is reduced to one-half (½), memory cells MC1 coupled to the plurality of word lines may be disposed in a given number and divided among the bit line BL and the complementary bit line BLB. Data of opposite logic may be respectively written to a first memory cell MC1 (coupled to the bit line BL and a word line WLa) and a second memory cell MC1 (coupled to the complementary bit line BLB and a word line WLj). For example, when data ‘1’ is stored in the first memory cell, data ‘0’ is stored in the second memory cell constituting a twinned pair in the dual structure.

FIG. 3 of the third embodiment shows a block 410 having a twin cell TC pair obtained by coupling memory cells to just a bit line BL of the bit line pair BL-BLB. For example, in FIG. 3, memory cells having a density of 256 Mbit per bank exist on bit line BL disposed in the right of the bit line sense amplifier 100. A density of, e.g., 128 Mbit or 64 Mbit, may be selected for just the memory cells coupled to the bit line BL.

In selecting a density of 128 Mbit (or 64 Mbit) as the MRS signal, where a normal density is 256 Mbit (or 64 Mbit) per bank, two (or four) word lines among the word lines sharing the bit line sense amplifier 100 are simultaneously activated. As a result, data corresponding to an externally equal address are written to (or read from) two (or four) memory cells.

In FIG. 3, memory banks A2 reduced to a density of ½ individually form a twin cell TC in the dual structure, and individually have a density of 128 Mbit. A memory bank A3 reduced to a density of ¼ forms a normal cell NC of 64 Mbit in the quad structure, and three banks A1 to A3 are twin cells TC of 196 Mbit in total in the quad structure.

In selecting the density as described above, a magnitude of cell capacitance can increase to twice or four times according to the need of user. As a result, the memory density is reduced corresponding to an increased level of cell capacitance magnitude, but the cycle of auto-refresh or self-refresh can be prolonged, thereby enabling a reduction in power consumption.

FIG. 4 illustrates an embodiment of the row decoder 10 shown in FIG. 1. The row decoder 10 may provide a circuit capable of simultaneously enabling multiple word lines, e.g., two word lines as referred to in FIG. 3, in response to the mode register set signal MRSS.

The row decoder 10 may have a wiring structure with pluralities of logic gates 42, 44, 46, 48, 50, 52, 54, 56, 58, 60, 64, 68, 72, 76, 80, 84, and 88. In a normal operation, one word line of eight word lines may be activated when internal address signals INTA0, INTA1, and INTA2 of 3 bits are applied in connection with a word line activation signal WL-ACT. When the determination mode allowing signal MRS1 is enabled, two word lines of eight word lines WL0 to WL7 may be activated simultaneously. Accordingly, data corresponding to an externally equal address may be written to (or read from) at least two memory cells simultaneously.

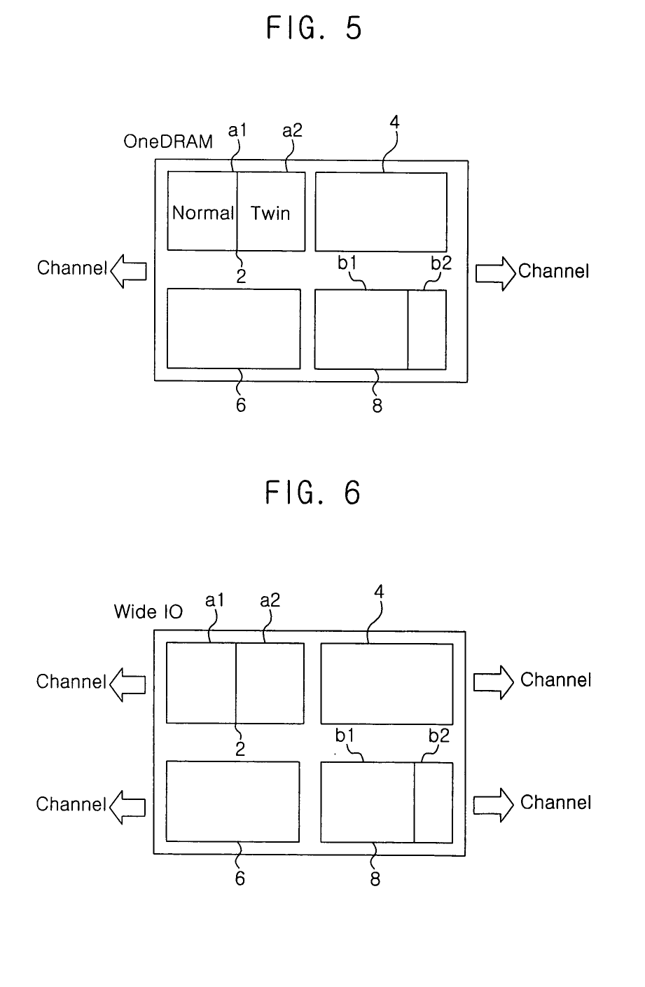

FIG. 5 illustrates an operation per bank in a memory, e.g., a mobile device memory, according to a fourth embodiment. FIG. 6 illustrates an operation per bank in a memory, e.g., a mobile device memory, according to a fifth embodiment. FIG. 5 illustrates an example for a oneDRAM™ memory and FIG. 6 illustrates an example for a wide I/O memory.

Referring to FIG. 5, a channel (port) on the left may be occupied by a first processor and a channel on the right may be occupied by second processor. When a first memory bank 2 (first of four memory banks 2, 4, 6, and 8) is predetermined as a memory bank dedicatedly accessed by the first processor, a memory use amount in a MODEM processing may not be more than application processing. Thus, the density of the first memory bank 2 may be reduced to one-half, operating like memory cores in FIG. 2 or 3. In this case, data corresponding to an externally equal address may be stored in two memory cells (one memory cell in each of blocks a1 and a2 of memory bank 2), so that the refresh cycle may be prolonged by a corresponding amount. Accordingly, power savings may be attained. Also illustrated in FIG. 5 is a quad structure in the fourth memory bank 8, where memory block b2 corresponds to normal cells NC (e.g., 64 Mbit in total) and block b1 corresponds to twinned cells TC (e.g., 196 Mbit in total), which together make up the quad structure.

In the wide I/O memory of FIG. 6, four channels are shown. Here again, the refresh requirement amount and memory-density may be set differently for respective channels. Thus, as an example, in managing the density of the first memory bank 2 and the fourth memory bank 8 as a ½ or ¼, respectively, by using the applied mode register set signal MRSS, the refresh time may be prolonged correspondingly.

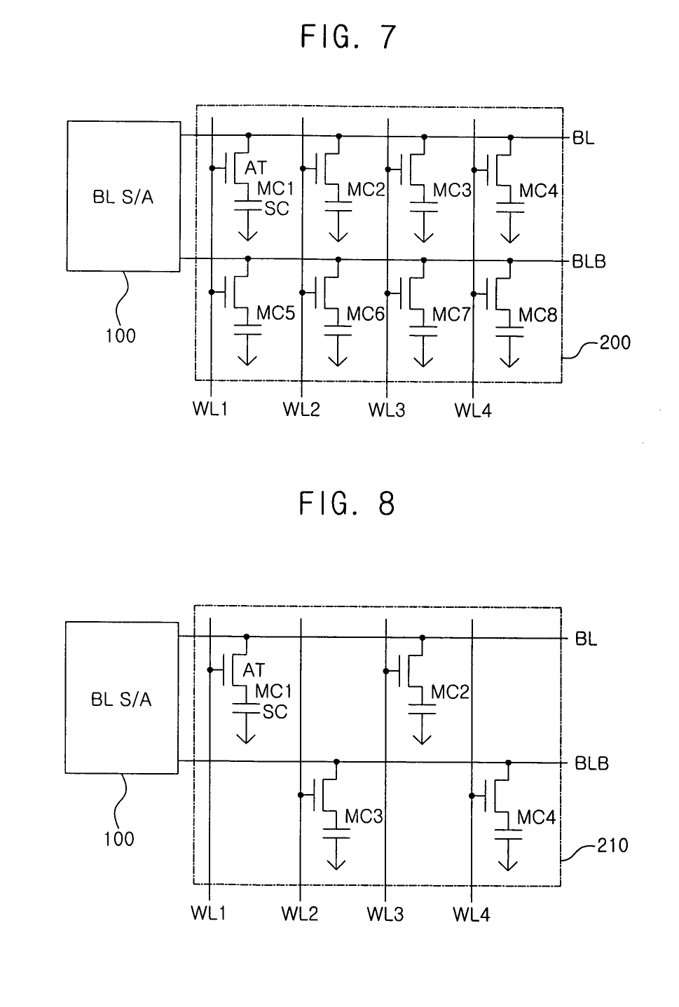

FIGS. 7 and 8 illustrate circuit diagrams of comparative memory cell arrays. In particular, FIG. 7 illustrates a twin-cell structure in which a block 200 has memory cells that share the same word line and are coupled to respective lines of a bit line pair BL-BLB. FIG. 8 illustrates a cell structure in which a block 210 has memory cells that are alternately coupled with a bit line BL and a complementary bit line BLB of bit line pair BL-BLB.

In the cell structure of FIG. 8, when a PASR operation is performed, a word line WL1 and a word line WL2 may be simultaneously activated in a twin-cell configuration. Similarly, a word line WL3 and a word line WL4 may be also activated at the same time. In this case, a control to individually write data of opposite logic to memory cells MC1 and MC3 may be required.

As described above, embodiments relate to a semiconductor memory device, and more particularly, to a semiconductor memory device having a refresh cycle that is variable during operation of the device, which may operate through a corresponding reduction in memory density. The memory density may be reduced when memory usage is relatively low. Thus, the refresh time may be increased, i.e., the frequency of the refresh may be reduced, and power consumption may be reduced correspondingly.

The refresh requirement amount and memory density may be selected according to a used channel (i.e., per-port) in the memory device, which may provide benefits in efficiency and/or power reduction as compared to a PASR operation. Such efficiency benefits and/or reductions in power consumption may be particularly useful for memories of mobile devices, battery-powered devices, etc. For example, for a memory bank of 256 Mbit employed as a memory of mobile device, the memory density may be selected as a memory capacity of 128 Mb, to twice prolong a refresh cycle and thereby lower power consumption. In this case, data corresponding to an address, which would normally be stored in one memory cell in the 256 Mbit configuration, may be stored as complementary (twin) data in two memory cells in the selected 128 Mbit configuration.

Example embodiments have been disclosed herein, and although specific terms are employed, they are used and are to be interpreted in a generic and descriptive sense only and not for purpose of limitation. For example, word lines may be activated to increase or reduce the number of memory cells enabled simultaneously, and by adapting other coupling structures of memory cells. In addition, although a mobile DRAM such as oneDRAM™, etc., is used as an example in the above-description, other volatile memories etc., i.e., pseudo-SRAM, etc., may also be used in a similar manner. Further, embodiments may be performed in a semiconductor memory device, e.g., DRAM, etc., used in a memory of a mobile system such as a portable media player (PMP), HHP, wireless telephone, data bank, personal data assistant (PDA), etc., or wherever low-power consumption is important. Accordingly, it will be understood by those of ordinary skill in the art that various changes in form and details may be made without departing from the spirit and scope of the present invention as set forth in the following claims.

What is claimed is:

1. A semiconductor memory device, comprising:
a bit line sense amplifier;
a bit line pair that includes a bit line and a complementary bit line, the bit line and the complementary bit line of the bit line pair each being coupled to the bit line sense amplifier;
a memory cell array having a plurality of memory banks, the memory banks including:
word lines, and
a plurality of memory cells coupled to each word line and coupled to at least one line of the bit line pair; and
a word line activation control unit, wherein:
the word line activation unit performs a control to access data corresponding to an externally same address in at least two memory cells by simultaneously activating a predetermined number of word lines from among the word lines sharing the bit line sense amplifier, and
the word line activation control unit operates in response to a determination mode allowing signal that is set in accordance with a used memory density.

2. The device as claimed in claim 1, wherein the determination mode allowing signal is varied by a mode register set signal.

3. The device as claimed in claim 2, wherein the predetermined number of word lines activated simultaneously is changed by a change of the mode register set signal, and then, when a self-refresh starts, a self-refresh cycle is changed depending on the mode register set signal.

4. The device as claimed in claim 2, wherein the word line activation control unit includes:
a mode register set unit receiving the mode register set signal and generating the determination mode-allowing signal;
an address and refresh control unit generating an address for an access of data and performing a refresh operation for data preservation in response to the determination mode allowing signal; and
a row decoder coupled to the address and refresh control unit, the row decoder simultaneously activating the predetermined number of word lines among the word lines sharing the bit line sense amplifier by performing a row address decoding operation in response to the determination mode allowing signal.

5. The device as claimed in claim 1, wherein the memory device includes at least two ports, the used memory density is selected per-port.

6. The device as claimed in claim 1, wherein the used memory density is changeable during operation of the device.

7. The device as claimed in claim 1, wherein the data in the at least two memory cells corresponding to the externally same address data is accessed using a same bit line sense amplifier.

8. The device as claimed in claim 7, wherein the plurality of word lines are all disposed collectively on one line of the bit line pair.

9. The device as claimed in claim 7, wherein the plurality of word lines are divided into respective groups on the bit line and the complementary bit line of the bit line pair.

10. The device as claimed in claim 9, wherein data of opposite logic are respectively written to a first memory cell coupled to the bit line and a word line in a first group and to a second memory cell coupled to the complementary bit line and a word line in a second group.

11. A semiconductor memory device, comprising:
a bit line sense amplifier;
a bit line pair that includes a bit line and a complementary bit line, the bit line and the complementary bit line of the bit line pair each being coupled to the bit line sense amplifier;
a memory cell array having a plurality of memory banks, the memory banks including:
word lines, and
a plurality of memory cells coupled to each word line and coupled to at least one line of the bit line pair; and
a word line activation control unit, wherein:
the word line activation unit performs a control to access data corresponding to an externally same address in memory cells adapted in numbers of 2n, n being a natural number, by simultaneously activating a predetermined number of word lines from among the word lines sharing the bit line sense amplifier in response to a mode register set signal.

12. The device as claimed in claim 11, wherein, when the number of activated memory cells is increased, a self-refresh cycle increases.

13. The device as claimed in claim 12, wherein the plurality of word lines are all disposed collectively on one line of the bit line pair.

14. The device as claimed in claim 12, wherein the plurality of word lines are divided into respective groups on the bit line and the complementary bit line of the bit line pair.

15. The device as claimed in claim 14, wherein data of opposite logic are respectively written to a first memory cell coupled to the bit line and a word line in a first group and to a second memory cell coupled to the complementary bit line and a word line in a second group.
